(19) United States
(12) Patent Application Publication
(10) Pub. No.: US 2010/0004882 A1
(43) Pub. Date: Jan. 7, 2010

(54) FAULT DETECTION AND CLASSIFICATION METHOD FOR WAFER ACCEPTANCE TEST PARAMETERS

(75) Inventors: YIJ CHIEH CHU, TAIPEI COUNTY (TW); CHUN CHI CHEN, TAIPEI CITY (TW); YUN-ZONG TIAN, TAICHUNG COUNTY (TW); CHENG-HAO CHEN, TAIPEI CITY (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY (TW)

(21) Appl. No.: 12/200,958

(22) Filed: Aug. 29, 2008

(30) Foreign Application Priority Data
Jul. 4, 2008 (TW) 97125212

(51) Int. Cl. G06F 17/18; G01R 31/00

(52) U.S. Cl. 702/58; 702/181

(57) ABSTRACT

A fault detection and classification (FDC) method for wafer acceptance test (WAT) parameters includes the following steps. A plurality of fault detection and classification parameters is collected. A plurality of wafer acceptance test parameters that are corresponded by the fault detection and classification parameters is collected. The fault detection and classification parameters are grouped. A contingency table of the wafer acceptance test parameters corresponding to the fault detection and classification parameters is built. A probability model of the contingency table is built. Finally, a safety range of the probability model is determined.

### BACKGROUND OF THE INVENTION

1. Field of the Invention

The present invention relates to a fault detection and classification method. In particular, the present invention relates to a fault detection and classification (FDC) method for wafer acceptance test (WAT) parameters.

2. Description of the Related Art

At the initial stage, semiconductor fabrication (fab) merely performs manufacturing control to a single manufacturing process. As the technology has been developed and progressed, the semiconductor fab develops the fab-wide solutions—the advanced process control (APC). The advanced process control includes run-to-run control (R2R control), and fault detection and classification (FDC). These two fields are developed for practical application level, such as chemical mechanical polishing (CMP), diffusion, lithography (especially for critical dimension, overlay), and etching, etc.

In addition to improve the performance of a single manufacturing process, both also improve the assembly line metrics, such as yield rate and throughput rate. Currently, the advanced process control is applied to the semiconductor fab integration. In addition to the conventional procedure guidance, the overall fab yield rate, the throughput rate, and the wafer acceptance test parameters are used as the target control.

Taiwan patent, TW I240983, is titled as a data analysis method for fault detection and classification system. Reference is made to FIG. 1, a data analysis method 100 for fault detection and classification (also named as fault detection classification) system is disclosed and includes the following steps. Step S102 is performed, wherein a plurality of raw data is obtained from the fault detection and classification system. Step S104 is performed, wherein according to a pre-determined selection condition, the plurality of raw data is spared to generate a classification data. Step S106 is performed, wherein a pre-determined statistics method is used for analyzing the classification data. The pre-determined selection condition is used for selecting the raw data corresponding to a wafer manufacturing process from the plurality of raw data. The predetermined selection condition is a threshold value that corresponds to the wafer manufacturing process. The step S104 selects the raw data that meets the threshold value so as to generate the classification data. The pre-determined statistics method is a T-test operation, a one-way analysis of variance operation, a data mining operation, or a discriminate analysis operation.

The assembly line metrics, including the yield rate and the throughput rate, is calculated by the T-test operation, the one-way analysis of variance operation, the data mining operation, or the discriminate analysis operation. For example, the threshold value for the yield rate is 90%, and the threshold value of the throughput rate is 95%. The bigger is the line metrics (the yield rate and the throughput rate), the better is the performance of the semiconductor manufacturing process.

However, the wafer acceptance test (WAT) parameters have a different trend at the fault detection and classification system. Some of the wafer acceptance test parameters use the larger value to represent the performance of the semiconductor manufacturing process as being better. Some of the wafer acceptance test parameters use the smaller value to represent the performance of the semiconductor manufacturing process as being better. Other wafer acceptance test parameters use a value that is between an upper limit value and a lower limit value as being the optimum value. The fault detection and classification system cannot control all of the wafer acceptance test parameters within an acceptable range. Therefore, the yield rate decreases and the throughput rate also decreases.

### SUMMARY OF THE INVENTION

One particular aspect of the present invention is to provide a fault detection and classification (FDC) method for wafer acceptance test (WAT) parameters to improve the yield rate and increases the throughput rate.

The fault detection and classification method for wafer acceptance test parameters includes the following steps. A plurality of fault detection and classification parameters is collected. A plurality of wafer acceptance test parameters that is corresponded by the fault detection and classification parameters is collected. The fault detection and classification parameters are grouped. A contingency table of the wafer acceptance test parameters corresponding to the fault detection and classification parameters is built. A probability model of the contingency table is built. Finally, a safety range of the probability model is determined.

The present invention also provides a fault detection and classification (FDC) method for wafer acceptance test (WAT) parameters, and includes the following steps. A contingency table is built. The contingency table has a plurality of wafer acceptance test parameters and a plurality of fault detection and classification parameters. A probability model of the contingency table is built. The probability model describes the probability distribution of the fault detection and classification parameters corresponding to the wafer acceptance test parameters. Finally, a safety range of the probability model is determined.

The present invention has the following characteristics:

1. When the engineer on the production line changes the fault detection and classification parameters, the engineer can check whether the wafer acceptance test parameters surpasses the safety range of the probability model or not according to probability model, so as to increase the throughput rate.

2. The probability model can make the engineer understand the relation between the wafer acceptance test parameters and the fault detection and classification parameters, and set the fault detection and classification parameters within the safety range of the probability model to improve the yield rate.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

The drawings included herein provide a further understanding of the present invention. A brief introduction of the drawings is as follows:

FIG. 1 is a flow chart of the data analysis method for fault detection and classification (FDC) system of the prior art;

FIG. 2 is a flow chart of the fault detection and classification (FDC) method for wafer acceptance test (WAT) parameters of the first embodiment of the present invention;

FIG. 3 is a first list-table diagram of the fault detection and classification (FDC) method for wafer acceptance test (WAT) parameters of the first embodiment of the present invention;

FIG. 4 is a second list-table diagram of the fault detection and classification (FDC) method for wafer acceptance test (WAT) parameters of the first embodiment of the present invention;

FIG. 5 is a third list-table diagram of the fault detection and classification (FDC) method for wafer acceptance test (WAT) parameters of the first embodiment of the present invention;

FIG. 6 is a curve diagram of the data distribution of the wafer acceptance test (WAT) parameters of the first embodiment of the present invention;

FIG. 7 is a flow chart of the fault detection and classification (FDC) method for wafer acceptance test (WAT) parameters of the second embodiment of the present invention;

FIG. 8A˜8I are curved diagrams of the data distribution of the wafer acceptance test (WAT) parameters corresponding to the fault detection and classification (FDC) parameters of the second embodiment of the present invention; and

FIG. 9 is a curved diagram of the data distribution of the wafer acceptance test (WAT) parameters of the second embodiment of the present invention.

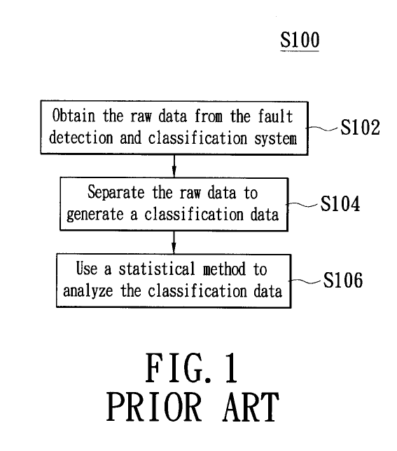

### DETAILED DESCRIPTION OF PREFERRED EMBODIMENTS

### The First Embodiment

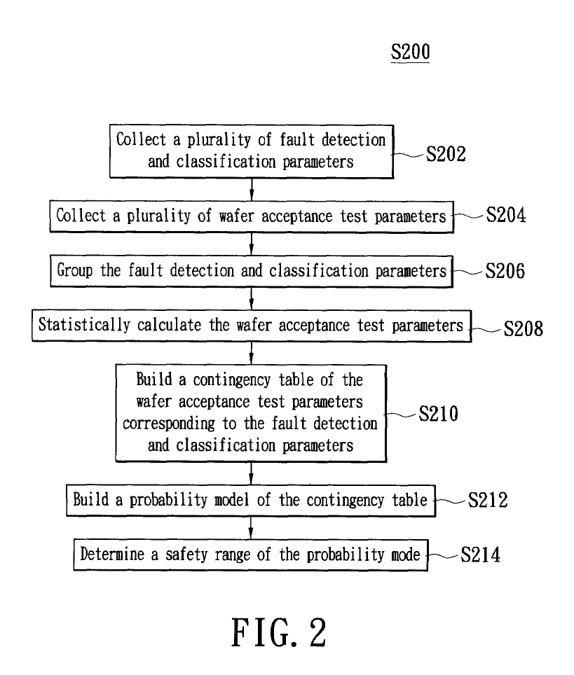

Reference is made to FIG. 2, which shows the fault detection and classification (FDC) method S200 for wafer acceptance test (WAT) parameters of the first embodiment of the present invention. The method includes the following steps.

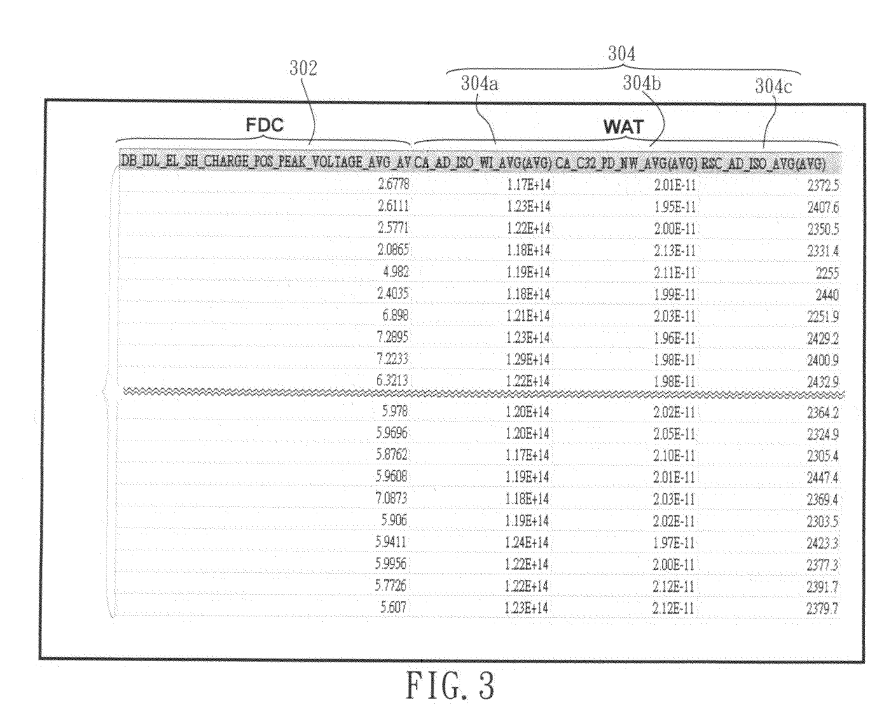

Step S202 is performed. Reference is made to FIG. 3. A plurality of fault detection and classification parameters 302 is collected. For example, the fault detection and classification parameters 302 are the plurality of manufacturing process parameters of a semiconductor manufacturing process machine.

Step S204 is performed. A plurality of wafer acceptance test parameters 304 that is corresponded by the fault detection and classification parameters 302 is collected. In this embodiment, the plurality of wafer acceptance test parameters 304 includes a plurality of first wafer acceptance test parameters 304a, a plurality of second wafer acceptance test parameters 304b, and a plurality of third wafer acceptance test parameters 304c.

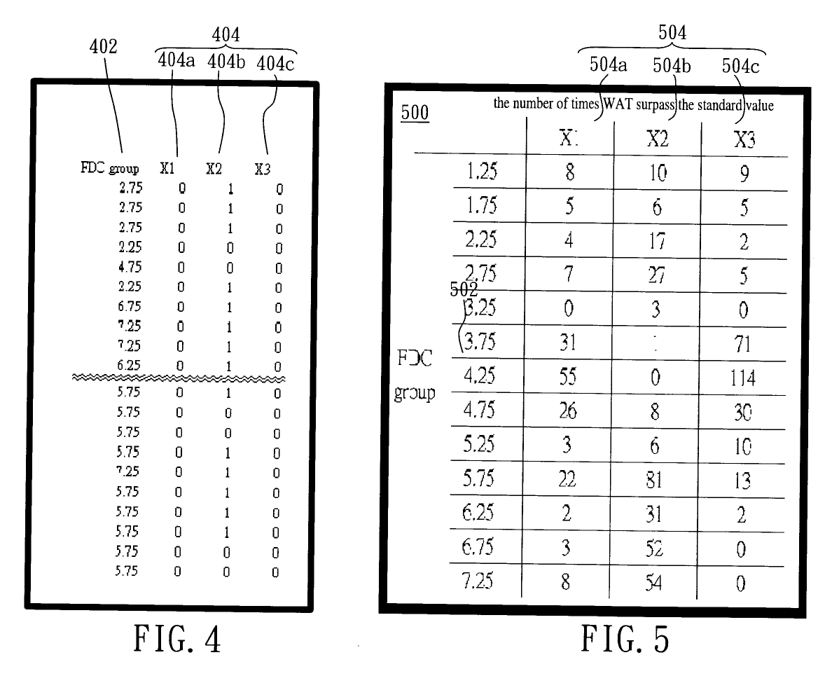

Step S206 is performed. Reference is made to FIG. 4. The fault detection and classification parameters 302 are grouped to generate a plurality of fault detection and classification parameter groups 402, 502 (also referring to FIG. 5). For example, the step of grouping the fault detection and classification parameters 302 is implemented by a statistical mean interval method, or determined by the engineer.

Step S208 is performed. The wafer acceptance test parameters 304 are calculated by the statistical method to obtain a plurality of standardized wafer acceptance test parameters (not shown in the figure). The mathematical formula of the standardized wafer acceptance test parameters is:

Z_{WAT}=(WAT− W̅A̅T̅)/S_{WAT}

WAT is the wafer acceptance test parameters 304. W̅A̅T̅ is the average of the wafer acceptance test parameters 304. S_{WAT} is the sample number of the standard deviation of the wafer acceptance test parameters 304. Z_{WAT} is the standardized wafer acceptance test parameters.

Step S210 is performed. Reference is made to FIG. 5. A contingency table 500 of the wafer acceptance test parameters 304 corresponding to the fault detection and classification parameters 302 is built.

Step S212 is performed. A probability model of the contingency table 500 is built. The probability model can be the first probability model, the second probability model, and the third probability model. According to the trend of the wafer acceptance test parameters 304, a proper probability model is selected. For example, the trend of the wafer acceptance test parameters 304 can be divided into three kinds, including the bigger the parameter, the better the performance of the manufacturing process machine; the smaller the parameter, the better the performance of the manufacturing process machine; and when the parameter is within an upper limit value and a lower limit value, then the performance of the manufacturing process machine is better.

In this embodiment, when the wafer acceptance test parameters 304 are bigger than an upper limit value (this trend is that the bigger the parameter, the better the performance of the manufacturing process machine), a proper first probability model is selected, and its formula is described as below. The upper limit value is set by an engineer.

π(X)=P(Z_{WAT}<−1|FDC)

log(π(X)/(1−π(X)=α+βX

X is the number of times 404, 504 that the wafer acceptance test parameters surpass the standard value. π(X) is the probability that the wafer acceptance test parameters 304 surpass the standard value. P(Z_{WAT}<−1|FDC) is the probability that the fault detection and classification parameters 302 corresponding to the standardized wafer acceptance test parameters is less than −1. α and β are the two coefficients of the curve-fitting function.

The number of times 404, 504 that the wafer acceptance test parameters 304 surpass the standard value include: the number of times 404a, 504a that the first wafer acceptance test parameters surpass the standard value, the number of times 404b, 504b that the second wafer acceptance test parameters surpass the standard value, and the number of times 404c, 504c that the third wafer acceptance test parameters surpass the standard value.

Furthermore, when the wafer acceptance test parameters 304 are less than a lower limit value (this trend is that the smaller the parameter, the better the performance of the manufacturing process machine), a proper second probability model is selected, and its formula is described as below. The lower limit value is set by an engineer.

π(X)=P(Z_{WAT}>1|FDC)

log(π(X)/(1−π(X))=α+βX

X is the number of times (not shown in the figure) that another wafer acceptance test parameters surpass the standard value. π(X) is the probability that the wafer acceptance test parameters 304 surpass the standard value. P(Z_{WAT}>1|FDC) is the probability that the fault detection and classification parameters 302 corresponding to the standardized wafer acceptance test parameters is greater than 1. α and β are the two coefficients of the curve-fitting function.

When the wafer acceptance test parameters 304 are within the upper limit value and the lower limit value (this trend is that when the parameter is within an upper limit value and a lower limit value, then the performance of the manufacturing process machine is better), a proper third probability model is selected, and its formula is described as below.

π(X)=P(Z_{WAT}<−1OR Z_{WAT}>1|FDC)

log(π(X)/(1−π(X))=α+βX

X is the number of times (not shown in the figure) that another wafer acceptance test parameters surpass the standard value. π(X) is the probability that the wafer acceptance test parameters 304 surpass the standard value. P(Z_{WAT}<−1 OR Z_{WAT}>1|FDC) is the probability that the fault detection and classification parameters 302 corresponding to the standardized wafer acceptance test parameters is greater than 1 or less than −1. α and β are the two coefficients of the curve-fitting function.

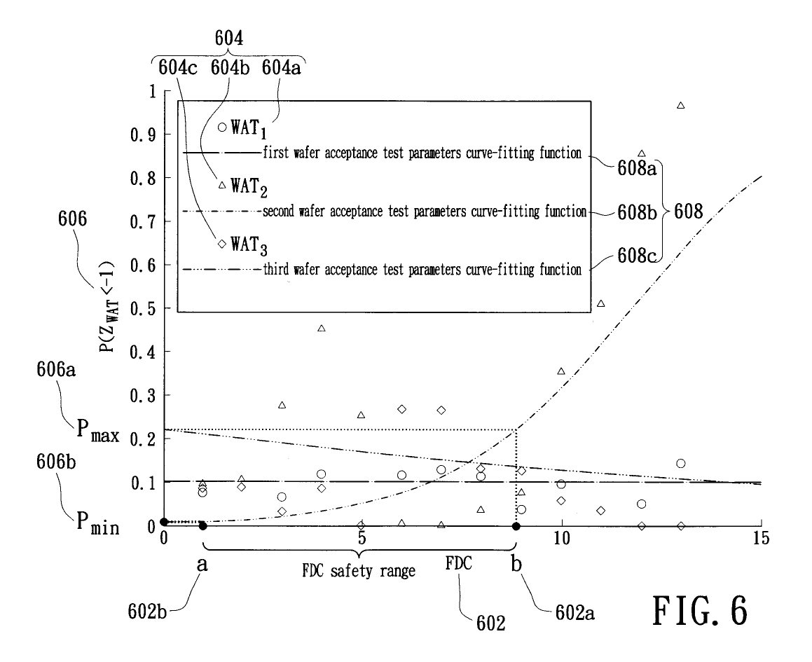

Reference is made to FIG. 6, which shows the curve diagram of the data distribution of the wafer acceptance test parameters 604 and the wafer acceptance test parameters curve-fitting function 608.

In this embodiment, the wafer acceptance test parameters 604 includes a plurality of first wafer acceptance test parameters 604a, a plurality of second wafer acceptance test parameters 604b, and a plurality of third wafer acceptance test parameters 604c.

In this embodiment, the wafer acceptance test parameters curve-fitting function 608 includes a first wafer acceptance test parameters curve-fitting function 608a, a second wafer acceptance test parameters curve-fitting function 608b, and a third wafer acceptance test parameters curve-fitting function 608c.

Finally, step S214 is performed to determine a safety range of the probability model. The safety range is between the upper limit value 602a of the fault detection and classification parameter 602 and the lower limit value 602b of the fault detection and classification parameter 602. X-coordinate is the fault detection and classification parameter 602. Y-coordinate is the probability 606 of the wafer acceptance test parameter surpassing the standard value. The probability 606 of the wafer acceptance test parameter surpassing the standard value includes the maximum value 606a of the probability 606 of the wafer acceptance test parameter surpassing the standard value, and the minimum value 606b of the probability 606 of the wafer acceptance test parameter surpassing the standard value.

### The Second Embodiment

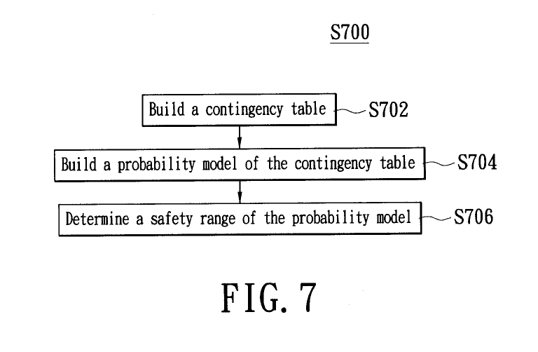

Reference is made to FIG. 7, which shows the fault detection and classification method S700 for wafer acceptance test parameters of the second embodiment of the present invention. The method includes the following steps.

Step S702 is performed. A contingency table (not shown in the figure) is built. The contingency table has a plurality of wafer acceptance test parameters (not shown in the figure) and a plurality of fault detection and classification parameters (not shown in the figure).

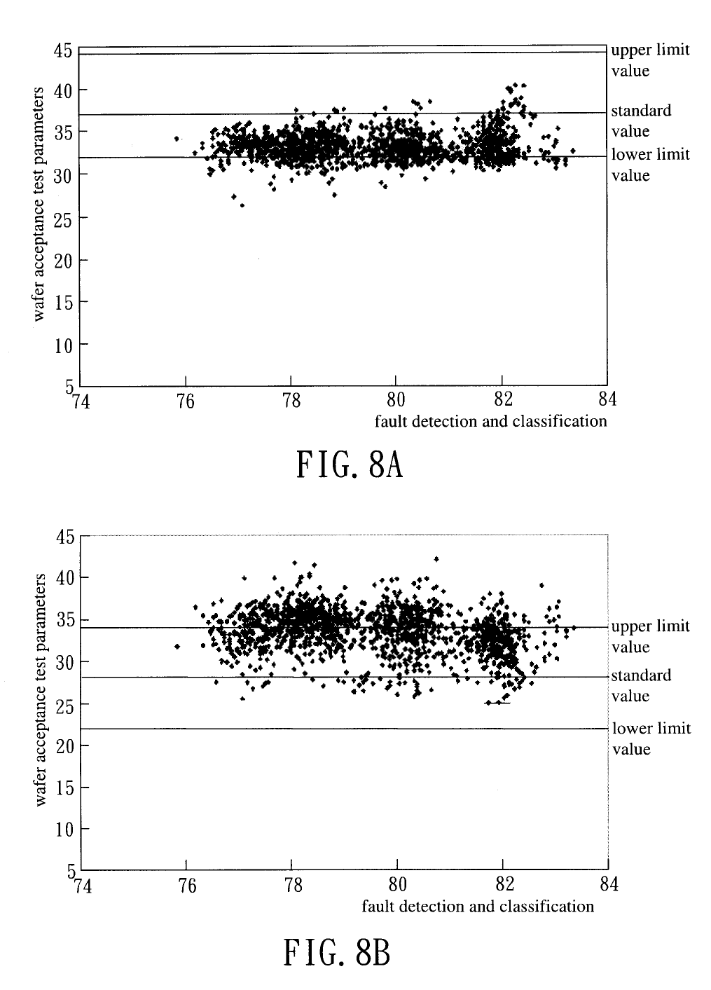

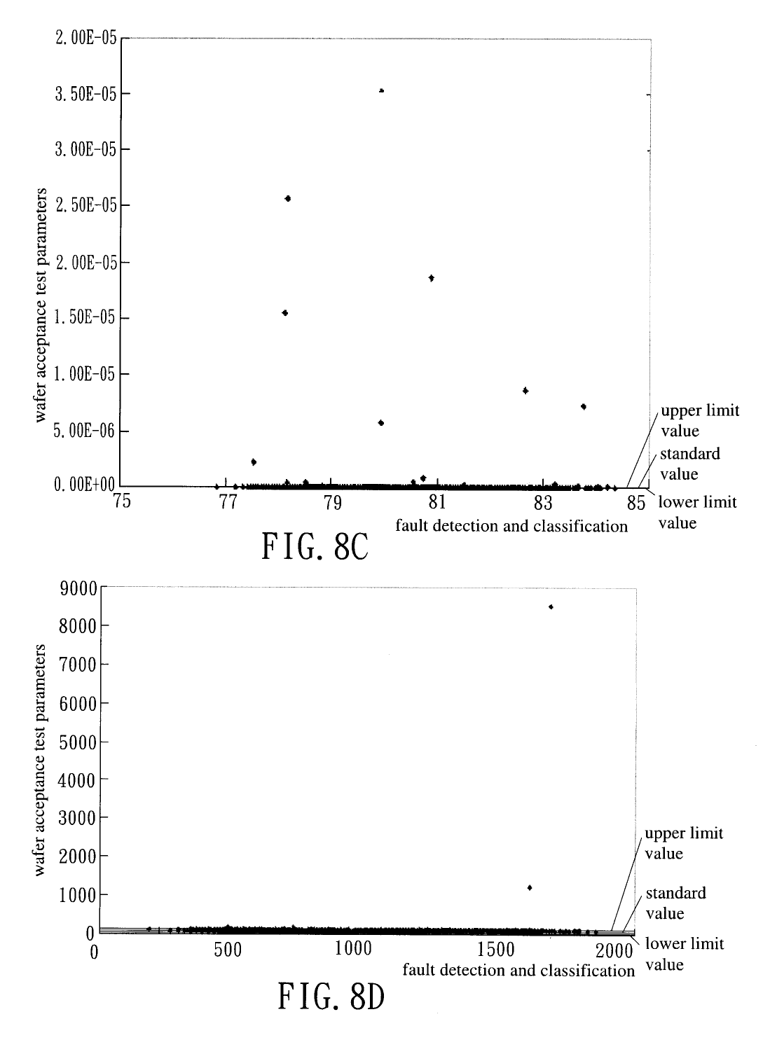

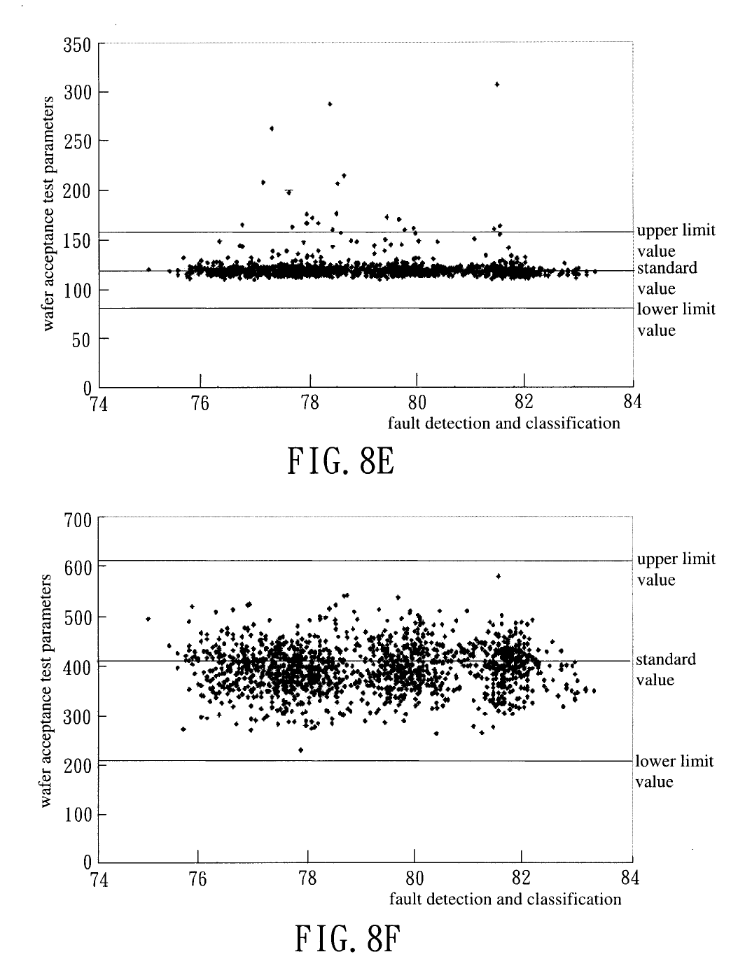

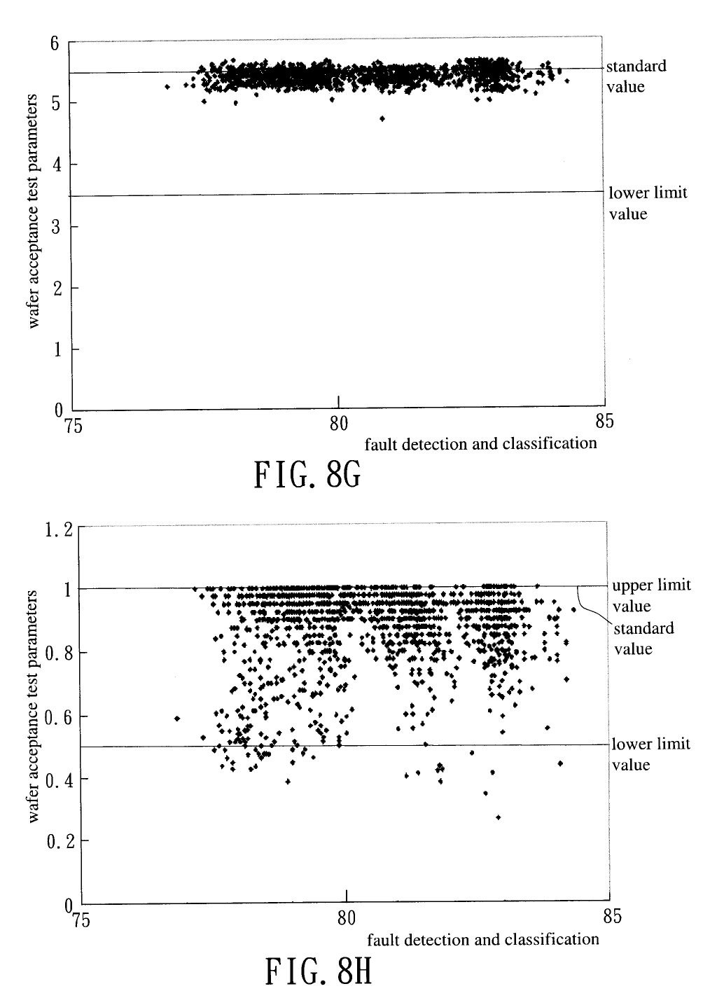

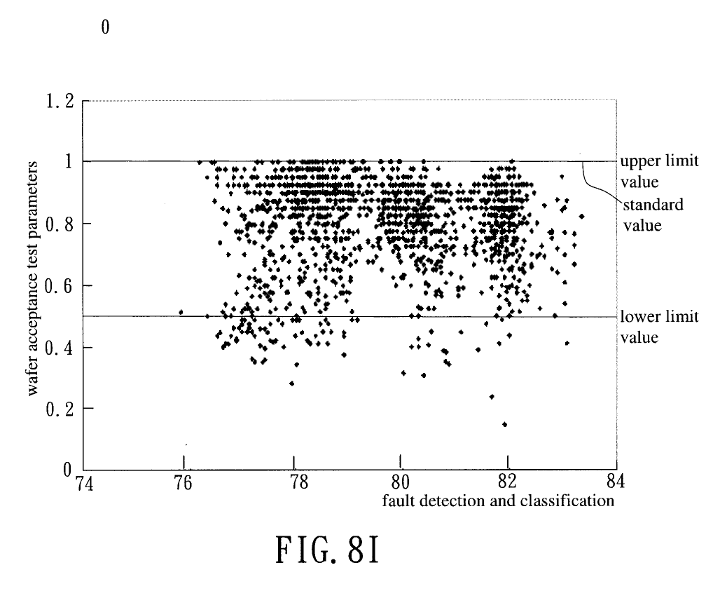

In this embodiment, referring to FIGS. 8A˜8I, which show the curved diagrams of the data distribution of the wafer acceptance test parameters corresponding to the fault detection and classification parameters. The flowing steps are also included. The fault detection and classification parameters are collected, the wafer acceptance test parameters corresponded by the fault detection and classification parameters are collected, and the fault detection and classification parameters are grouped.

Step S704 is performed. A probability model of the contingency table is built. The probability model describes the probability distribution of the fault detection and classification parameters corresponding to the wafer acceptance test parameters. The mathematical formula of the probability model is:

π(X)=P(WAT<L OR WAT>U|FDC)

log(π(X)/(1−π(X))=α+βX

X is the number of times that the wafer acceptance test parameters surpass the standard value. π(X) is the probability that the wafer acceptance test parameters surpass the standard value. P(Z_{WAT}<−L OR Z_{WAT}>U|FDC) is the probability that the fault detection and classification parameters 302 corresponding to the standardized wafer acceptance test parameters is less than the lower limit value (L) or greater than the upper limit value (U). α and β are the two coefficients of the curve-fitting function.

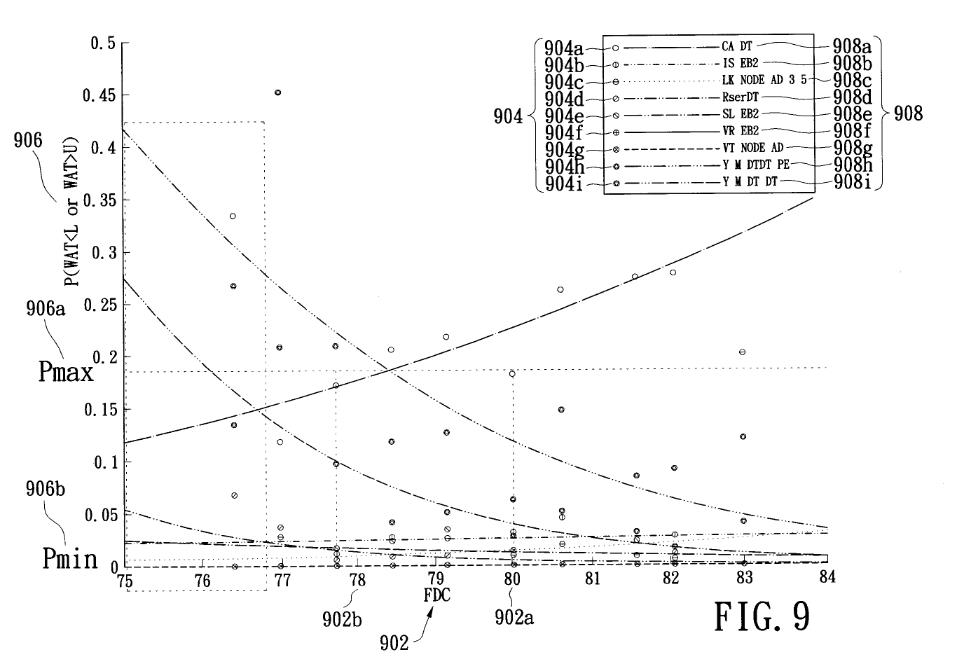

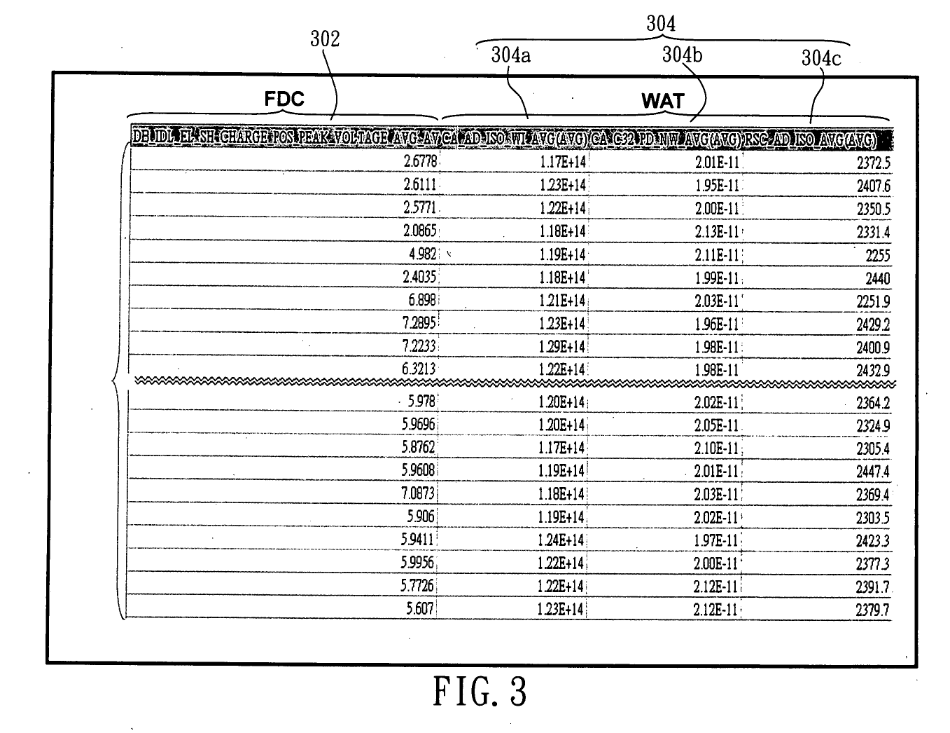

Reference is made to FIG. 9, which shows the curve diagram of the data distribution of the wafer acceptance test parameters 904 and the wafer acceptance test parameters curve-fitting function 908.

In this embodiment, the wafer acceptance test parameters 904 includes a plurality of first wafer acceptance test parameters 904a (CA_DT), a plurality of second wafer acceptance test parameters 904b (IS_EB2), a plurality of third wafer acceptance test parameters 904c (LK_NODE_AD_{—}3_{—}5), a plurality of fourth wafer acceptance test parameters 904d (ResrDT), a plurality of fifth wafer acceptance test parameters 904e (SL_EB2), a plurality of sixth wafer acceptance test parameters 904f (VR_EB2), a plurality of seventh wafer acceptance test parameters 904g (VT_NODE_AD), a plurality of eighth wafer acceptance test parameters 904h (Y_M_DTDT_PE), and a plurality of ninth wafer acceptance test parameters 904i (Y-M_DT_DT).

In this embodiment, the wafer acceptance test parameters curve-fitting function 908 includes a first wafer acceptance test parameters curve-fitting function 908a, a second wafer acceptance test parameters curve-fitting function 908b, a third wafer acceptance test parameters curve-fitting function 908c, a fourth wafer acceptance test parameters curve-fitting function 908d, a fifth wafer acceptance test parameters curve-fitting function 908e, a sixth wafer acceptance test parameters curve-fitting function 908f, a seventh wafer acceptance test parameters curve-fitting function 908g, an eighth wafer acceptance test parameters curve-fitting function 908h, and a ninth wafer acceptance test parameters curve-fitting function 908i.

Finally, step S706 is performed to determine a safety range of the probability model. The safety range is between the upper limit value 902a of the fault detection and classification parameter 902 and the lower limit value 902b of the fault detection and classification parameter 902. X-coordinate is the fault detection and classification parameter 902. Y-coordinate is the probability 906 of the wafer acceptance test parameter surpassing the standard value. The probability 906 of the wafer acceptance test parameter surpassing the standard value includes the maximum value 906a of the probability 906 of the wafer acceptance test parameter surpassing the standard value, and the minimum value 906b of the probability 906 of the wafer acceptance test parameter surpassing the standard value.

The present invention has the following characteristics:

1. When the engineer on the production line changes the fault detection and classification parameters 302, 602, 902, the engineer can check whether the wafer acceptance test parameters 304, 604, 904 surpasses the safety range of the probability model or not according to probability model so as to increase the throughput rate.

2. The probability model can make the engineer understand the relation between the wafer acceptance test parameters 304, 604, 904 and the fault detection and classification parameters 302, 602, 902, and set the fault detection and classification parameters 302, 602, 902 within the safety range of the probability model so as to improve the yield rate.

3. By referring to the wafer acceptance test parameters 604, 904 and the wafer acceptance test parameters curve-fitting function 608, 908 of the probability model, the engineer can check the manufacturing process by a visually according to figures/graphics so as to achieve the process risk control.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. A fault detection and classification (FDC) method for wafer acceptance test (WAT) parameters, comprising:
collecting a plurality of fault detection and classification parameters;
collecting a plurality of wafer acceptance test parameters that is corresponded by the fault detection and classification parameters;
grouping the fault detection and classification parameters;
building a contingency table of the wafer acceptance test parameters corresponding to the fault detection and classification parameters;
building a probability model of the contingency table; and
determining a safety range of the probability model.

2. The fault detection and classification method for wafer acceptance test parameters as claimed in claim 1, further comprising statistically calculating the wafer acceptance test parameters to obtain a plurality of standardized wafer acceptance test parameters.

3. The fault detection and classification method for wafer acceptance test parameters as claimed in claim 2, wherein the formula of the standardized wafer acceptance test parameters is:
Z_{WAT}=(WAT− W̅A̅T̅)/S_{WAT}
Wherein WAT is the wafer acceptance test parameters, W̅A̅T̅ is the average of the wafer acceptance test parameters, S_{WAT} is the sample number of the standard deviation of the wafer acceptance test parameters, and Z_{WAT} is the standardized wafer acceptance test parameters.

4. The fault detection and classification method for wafer acceptance test parameters as claimed in claim 2, wherein the formula of the probability model is:
π(X)=P(Z_{WAT}<−1|FDC)
log(π(X)/(1−π(X))=α+βX
wherein X is the number of times that the wafer acceptance test parameters surpass the standard value, π(X) is the probability that the wafer acceptance test parameters surpass the standard value, P(Z_{WAT}<−1|FDC) is the probability that the fault detection and classification parameters corresponding to the standardized wafer acceptance test parameters is less than −1, and α and β are the two coefficients of the curve-fitting function.

5. The fault detection and classification method for wafer acceptance test parameters as claimed in claim 4, wherein the wafer acceptance test parameters are greater than an upper limit value.

6. The fault detection and classification method for wafer acceptance test parameters as claimed in claim 2, wherein the formula of the probability model is:
π(X)=P(Z_{WAT}>1|FDC)
log(π(X)/(1−π(X))=α+βX
wherein X is the number of times that the wafer acceptance test parameters surpass the standard value, π(X) is the probability that the wafer acceptance test parameters surpass the standard value, P(Z_{WAT}>1|FDC) is the probability that the fault detection and classification parameters corresponding to the standardized wafer acceptance test parameters is greater than 1, and α and β are the two coefficients of the curve-fitting function.

7. The fault detection and classification method for wafer acceptance test parameters as claimed in claim 6, wherein the wafer acceptance test parameters are less than a lower limit value.

8. The fault detection and classification method for wafer acceptance test parameters as claimed in claim 2, wherein the formula of the probability model is:
π(X)=P(Z_{WAT}<−1 OR Z_{WAT}>1|FDC)
log(π(X)/(1−π(X))=α+βX
wherein X is the number of times that the wafer acceptance test parameters surpass the standard value, π(X) is the probability that the wafer acceptance test parameters surpass the standard value, P(Z_{WAT}<−1 OR Z_{WAT}>1|FDC) is the probability that the fault detection and classification parameters corresponding to the standardized wafer acceptance test parameters is greater than 1 or less than −1, and α and β are the two coefficients of the curve-fitting function.

9. The fault detection and classification method for wafer acceptance test parameters as claimed in claim 8, wherein the wafer acceptance test parameters are within an upper limit value and a lower limit value.

10. The fault detection and classification method for wafer acceptance test parameters as claimed in claim 4, wherein the safety range is composed of an upper limit value and a lower limit value of the wafer acceptance test parameters.

11. The fault detection and classification method for wafer acceptance test parameters as claimed in claim 6, wherein the safety range is composed of an upper limit value and a lower limit value of the wafer acceptance test parameters.

12. The fault detection and classification method for wafer acceptance test parameters as claimed in claim 8, wherein the safety range is composed of an upper limit value and a lower limit value of the wafer acceptance test parameters.

13. A fault detection and classification method for wafer acceptance test parameters, comprising:
building a contingency table, wherein the contingency table has a plurality of wafer acceptance test parameters and a plurality of fault detection and classification parameters;
building a probability model of the contingency table, wherein the probability model describes the probability distribution of the fault detection and classification parameters corresponding to the wafer acceptance test parameters; and
determining a safety range of the probability model.

14. The fault detection and classification method for wafer acceptance test parameters as claimed in claim 13, further comprising:
statistically calculating the wafer acceptance test parameters; and
obtaining a plurality of standardized wafer acceptance test parameters.

15. The fault detection and classification method for wafer acceptance test parameters as claimed in claim 13, wherein the step of building a contingency table further comprises:
collecting a plurality of fault detection and classification parameters;
collecting a plurality of wafer acceptance test parameters that is corresponded by the fault detection and classification parameters; and
grouping the fault detection and classification parameters.

16. The fault detection and classification method for wafer acceptance test parameters as claimed in claim 14, wherein the formula of the probability model is:
π(X)=P(WAT<L OR WAT>U|FDC)
log(π(X)/(1−π(X))=α+βX
wherein X is the number of times that the wafer acceptance test parameters surpass the standard value, π(X) is the probability that the wafer acceptance test parameters surpass the standard value, P(Z_{WAT}<−L OR Z_{WAT}>U|FDC) is the probability that the fault detection and classification parameters corresponding to the standardized wafer acceptance test parameters is less than a lower limit value or greater than an upper limit value, α and β are the two coefficients of the curve-fitting function.

17. The fault detection and classification method for wafer acceptance test parameters as claimed in claim 15, wherein the formula of the probability model is:
π(X)=P(WAT<L OR WAT>U|FDC)
log(π(X)/(1−π(X))=α+βX
wherein X is the number of times that the wafer acceptance test parameters surpass the standard value, π(X) is the probability that the wafer acceptance test parameters surpass the standard value, P(Z_{WAT<-L OR Z}_{WAT}>U|FDC) is the probability that the fault detection and classification parameters corresponding to the standardized wafer acceptance test parameters is less than a lower limit value or greater than an upper limit value, α and β are the two coefficients of the curve-fitting function.

18. The fault detection and classification method for wafer acceptance test parameters as claimed in claim 13, wherein the safety range is composed of an upper limit value and a lower limit value of the wafer acceptance test parameters.
